(19) United States
(12) Patent Application Publication
(10) Pub. No.: US 2015/0115976 A1
(43) Pub. Date: Apr. 30, 2015

(54) CONTINUOUS WEB INLINE TESTING APPARATUS, DEFECT MAPPING SYSTEM AND RELATED METHODS

(71) Applicant: Celgard, LLC, Charlotte, NC (US)

(72) Inventors: Changqing Wang Adams, Fort Mill, SC (US); C. Shane Landes, Clover, SC (US); Douglas George Robertson, Charlotte, NC (US); Mark W. Ferebee, Charlotte, NC (US)

(73) Assignee: Celgard, LLC, Charlotte, NC (US)

(21) Appl. No.: 14/521,747

(22) Filed: Oct. 23, 2014

Related U.S. Application Data
(60) Provisional application No. 61/895,572, filed on Oct. 25, 2013.

(51) Int. Cl. G01R 31/12

(52) U.S. Cl. CPC G01R 31/1227; G01R 31/1218
USPC 324/554

(57) ABSTRACT

In at least selected embodiments, an industrial size continuous Hipot testing system has defect mapping capability capable of finding pinholes, weak spots, and/or embedded conductive particles in non-conductive sheet materials. Continuous testing is made possible through a pair of uniquely designed rollers, such as conductive polymer rollers. Automatic defect mapping is also incorporated into the system through the integration of the Hipot testing and line scan camera systems. The unit potentially has wide applications in many industries, such as, for example, semi-conductors and electronics, medical, high end packaging, and so forth.

### CROSS-REFERENCE TO RELATED APPLICATION

The instant application claims the benefit of and priority to U.S. Provisional Patent Application Ser. No. 61/895,572, filed Oct. 25, 2013.

### FIELD OF THE INVENTION

In accordance with at least selected embodiments, the instant invention relates to a new, improved or optimized continuous web inline testing apparatus, defect mapping system, and/or related methods. In accordance with at least certain embodiments, the instant invention relates to a continuous web inline testing apparatus adapted for use in a defect mapping system and to related methods of testing and mapping. More particularly, the instant invention relates to a new, improved or optimized continuous inline Hipot testing system. Even more specifically, the instant invention relates to inline Hipot testing on continuous non-conductive web material, which testing may detect defects and then map and record such defects automatically by a line scan camera system for quality grading purposes. In accordance with at least certain selected embodiments, an industrial size continuous Hipot testing system with defect mapping capability capable of finding pinholes, weak spots and embedded conductive particles in non-conductive sheet materials. In various embodiments, continuous testing is made possible through a pair of uniquely designed conductive polymer rollers, and automatic defect mapping is incorporated into the system through the integration of the Hipot testing and line scan camera systems. The unit potentially has wide applications in many industries, by way of example, semi-conductor and electronics, medical, high end packaging, and the like.

### BACKGROUND OF THE INVENTION

Detecting pinholes or weak spots that are prone to shorting in insulating material is critical to the electronic industry. To detect flaws in a continuous manufacturing environment, inline voltage withstand and pinhole detection is highly desired. At the moment, optical inspection with camera is the most widely adopted technology. The technology, although somewhat suitable for continuous web operation, is not 100% reliable to detect very small holes due to limited camera pixel resolution. Also, cameras cannot detect weak, thin or damaged spots on the web that are not optically different. Thus, various limitations exist related to using only an optical method (e.g., human eye observation only or camera only) for detecting defects in a continuous roll, sheet or web of material, since many defects, such as pinhole defects, may not be visible to a naked eye or standard optical camera.

One reliable way to detect any size of pinhole or defect may be Hipot testing. “Hipot” as is known in the art is an abbreviation for “high potential.” Although there are one or more manufacturers making inline Hipot or pinhole testing equipment, the equipment is primitive, limited in use, and requires draping a metal beaded curtain over the moving web while applying the voltage. In such systems, the bottom portion of the system may be a metal roller, while the top portion of the system may be a metal beaded curtain that drags across the moving web material while a voltage is applied, to aid in detecting a defect (such as a pinhole or weak spot) in the moving web material. The beaded curtain not only could damage sensitive web material, but also may not provide the desired coverage of the tested area. Further, the metal beads themselves may become damaged or pitted on the surface due to high voltage shorts.

Additionally, prior art Hipot systems cannot map the defects in the moving web, and that makes current testing lose its main purpose, namely identifying defects to an operator so that decisions may be made, if any, regarding the continuous web or sheet material.

Therefore, there is clearly a need to develop an inline Hipot testing system that is continuous, gentle on the web material, and involves improved defect detection capability as well as mapping capability.

### SUMMARY OF THE INVENTION

In accordance with at least selected embodiments, aspects or objects of the invention, the above issues, problems and/or needs are addressed by at least selected embodiments of the instant invention related to new, improved or optimized continuous web inline testing apparatus, defect mapping systems, and/or related methods. In accordance with at least certain embodiments, the instant invention relates to a continuous web inline testing apparatus adapted for use in a defect mapping system and to related methods of testing and mapping. More particularly, the instant invention relates to a new, improved or optimized continuous inline Hipot testing system. Even more specifically, the instant invention relates to inline Hipot testing on continuous non-conductive web material, which testing may detect defects and then map and record such defects automatically by a line scan camera system for quality grading purposes. In accordance with at least certain selected embodiments, an industrial size continuous Hipot testing system with defect mapping capability capable of finding pinholes, weak spots and embedded conductive particles in non-conductive sheet materials. In various embodiments, continuous testing is made possible through a pair of uniquely designed conductive polymer rollers, and automatic defect mapping is incorporated into the system through the integration of the Hipot testing and line scan camera systems. The unit potentially has wide applications in many industries, by way of example, semi-conductor and electronics, medical, high end packaging, and the like.

### BRIEF DESCRIPTION OF THE DRAWINGS

FIG. 1 is a schematic side view drawing of an exemplary machine for testing two ply materials in accordance with at least selected embodiments of the instant invention.

FIG. 2 is a detailed perspective view drawing of at least one embodiment of exemplary conductive polymer nip rollers and mounting in accordance with at least selected embodiments of the instant invention.

FIG. 3 is an example image of a section of an optical inspection roll map with detected repeating pattern and flaws in accordance with at least one embodiment or example of the instant invention.

### DETAILED DESCRIPTION OF THE INVENTION

At least certain selected embodiments of the instant invention are designed to at least address at least some of the above mentioned issues, needs and/or problems.

In accordance with at least selected embodiments, the instant invention relates to a new, improved or optimized continuous web inline testing apparatus, defect mapping system, and/or related methods. In accordance with at least certain embodiments, the instant invention relates to a continuous web inline testing apparatus adapted for use in a defect mapping system and to related methods of testing and mapping. More particularly, the instant invention relates to a new, improved or optimized continuous inline Hipot testing system. Even more specifically, the instant invention relates to inline Hipot testing on continuous non-conductive web material, which testing may detect defects and then map and record such defects automatically by a line scan camera system for quality grading purposes. In accordance with at least certain selected embodiments, an industrial size continuous Hipot testing system with defect mapping capability that is capable of finding pinholes, weak spots, and/or embedded conductive particles in non-conductive sheet materials, and continuous testing is made possible through a pair of uniquely designed rollers, which, in some embodiments, are conductive polymer rollers. Automatic defect mapping is also incorporated into the system through the integration of the Hipot testing and line scan camera systems, and the unit potentially has wide applications in many industries, such as, by way of example, semi-conductor and electronics, medical, high end packaging, and so forth.

In accordance with at least one embodiment, the invention is directed toward a continuous inline web Hipot testing system with defect mapping capability. In select embodiments, the continuous Hipot testing machine may be used for testing insulating sheet material for the electronic industry. Any defects, such as pinholes, weak spots and/or defects embedded with conductive particles may be detected by the machine. This machine described in the instant invention may be especially designed to test thin microporous polymer membrane, such as thin or ultrathin microporous polyolefin membranes, composites or layers, which may make up part or all of a battery separator for rechargeable lithium ion batteries. The thicker separator material used for lead acid batteries also may be tested with this equipment. Because the machine may be used for testing “leak” or “potential leak”, it also may be used to inspect porous or non-porous, non-conductive sheet materials for medical use, and high end packaging. For example, the machine described herein may be designed to test various other insulting sheet material or continuous webs of material (by way of example only, a continuous sheet of material used in a medical application to encapsulate pharmaceuticals, such as pills or capsules, filter material, garment material, or the like). In summary, due to the versatility of the technology, it may be used by many industries, such as, by way of example, electronics, medical, chemical, aerospace, automotive, etc., using a wide variety of preferably non-conductive materials, components or precursors as the material to be tested.

In certain embodiments, the system may be incorporated into a production line or a converting winder. The winder can be for single or multiple plies of operation. Several examples described herein may be for a two ply winder; however, the invention is not limited thereto, and other winders may be used with any number of plies of or from the non-conductive material to be tested.

The operating sequences of the system of at least selected embodiments may be: a roll of sheet material comprising multiple plies (for example, two plies) is loaded to an unwind arbor. The plies may first be separated, then Hipot tested for pinholes and weak spots. Such Hipot testing includes a Hipot tester that is connected to the rollers described herein, which may, in certain preferred embodiments, be conductive polymer rollers. The burnt spots in the moving web material being tested, which spots result from the Hipot failures, may be mapped by line scan cameras for quality grading purposes. The tested material is then collected at the rewinds as rolls.

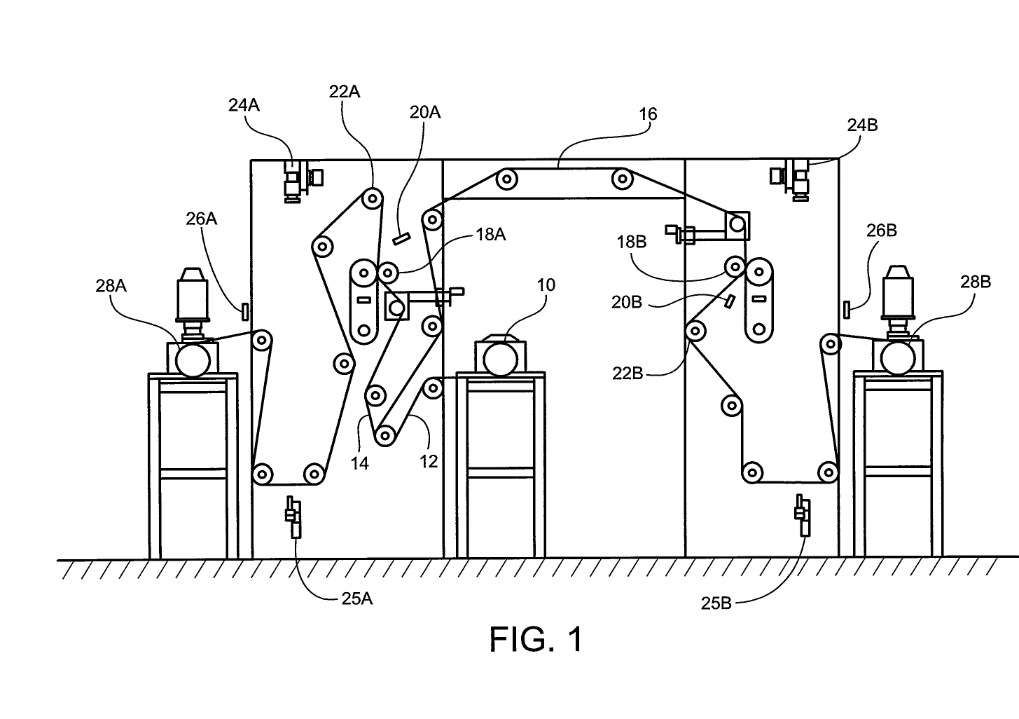

FIG. 1 is a schematic drawing of an exemplary entire machine and system. In select embodiments of the instant invention, the components of the testing system may include, but are not limited to:
(i) A pair of nip rollers, for example, conductive polymer coated nip rollers;
(ii) One or more static removal devices;
(iii) Line-scan camera system;
(iv) One or more Hipot testers;
(v) Unwind and rewind with a tension control system; and
(vi) PLC (programmable logic controller) for integrating the winding machine with a touch screen HMI for operator interface, Hipot testers, camera inspection systems.

Select embodiments of the detailed operation of the machine, apparatus, and/or system may include the following:

The following discussion relates to FIG. 1 by way of example only. In FIG. 1, to prepare for testing, a roll of material (here, two-ply material 12) may be loaded onto an unwind arbor 10. In various embodiments of the present invention, a sample or representative roll (for example, a roll of 50 feet of material) might be Hipot tested in accordance with the instant invention to determine, representatively, what the properties of the entire production roll of material are probably like (e.g., an entire production roll of material might be 1500-3000 meters long). However, in other embodiments, a user or manufacturer could test more than just a smaller, representative sample or roll of material.

Tie in footage may then be pulled from the roll, separated, and threaded through the machine to the rewinds (see rewinds 28A and 28B in FIG. 1). To begin the web inspection, the winder may run at “crawl” speed with the Hipot testers not activated. While doing this, the web may be aligned to fully cover one roller, for example, the smaller and removable conductive polymer roller (or the roller that includes both conductive and non-conductive portions), all of which rollers are described in more detail below, making sure the conductive portion of two rollers do not make contact with one another.

To start testing, the operator may push the “Run” button on the HMI and the machine may be programmed to run at a designated preset speed for a predetermined length. The speed of the web material through the machine may be, for example, 5-50 feet per minute, and in some embodiments, 5-25 feet per minute. In some embodiments, the speed may be much higher, in keeping with production speeds of web material (for example, up to about 50 meters/minute, or even higher in various embodiments).

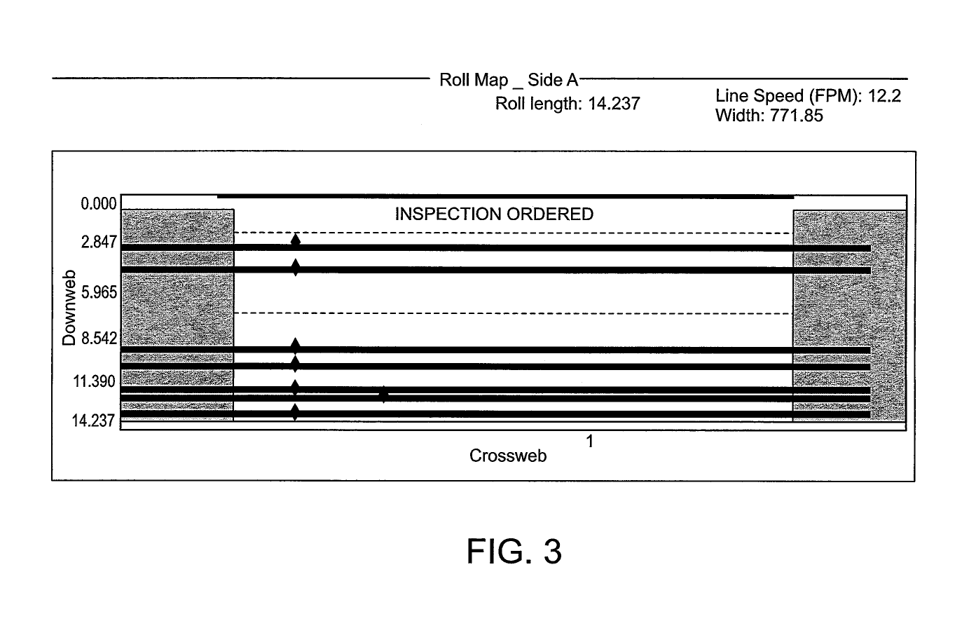

When the machine is started, the Hipot tester(s) and optical inspection system may be activated automatically through the PLC. The unwinding web material 12 may first be separated into two plies of web material, a first ply 14 and a second ply 16. The discussion below follows first ply 14 through the left side of FIG. 1; but it should be understood that second ply 16 shown in FIG. 1 goes through the same type of process and procedure on the right side of FIG. 1. As first ply 14 moves along for testing, the static in such material may be discharged by an anti-static bar 20A. The separate webs may then be Hipot tested in between the set of nipped conductive polymer rollers 18A (or 18B for second ply 16). During the Hipot testing, the nipped conductive polymer rollers 18A or 18B essentially act as electrodes, with one such electrode placing a voltage on the moving web material (such as first ply 14) and determining whether the web material can withstand such voltage or whether it fails when encountering such voltage, suggesting a defect. Thus, as the web material to be tested moves along, it is essentially acting as an insulator between two conductive rollers. When the material fails, a burnt spot occurs on the web material at the defect because of the failure. After the Hipot testing in between conductive polymer rollers 18A (or 18B), the web may go over one or more grounded rollers (such as grounded rollers 22A or 22B) to remove the charge stored in the material. The web may then pass through the optical inspection area of the machine for the mapping of the burnt defects. In FIG. 1, the optical inspection area of the machine includes line scan camera 24A (or camera 24B for the second ply 16 of material) as well as light source 25A (or 25B) for lighting the web material for inspection by the camera 24A. The line scan camera 24A collects information about the burnt defects on the moving web material. A detailed roll map and report (see FIG. 3) showing cross and down web positions of the defects may then be created automatically at the end of the run. Such detailed roll map may show a user, for example, how many burnt defects occurred, their locations, whether such defects are on one side of the web material, on a different side of the web material, in the middle of the web material, whether such defects are in a pattern, and/or whether such defects in the material are simply random.

Static is then further removed from the tested material using, for example, anti-static bar 26A (or 26B for the second ply 16), and the tested material of first ply 14 is rewound on rewind 28A. In various embodiments, the testing described herein may be considered destructive testing in that the representative sample rewound onto rewind 28A (or 28B) is not used any further other than to alert a user to any repeating pattern of defects. However, in other embodiments, rewound material may be further used as production material if the flaws are clearly identified either by map or marking, if it is not flawed, or the like.

The following may include other detailed descriptions of select embodiments of various components, and how they may function within the system.

(i) a Pair of Conductive Nip Rollers:

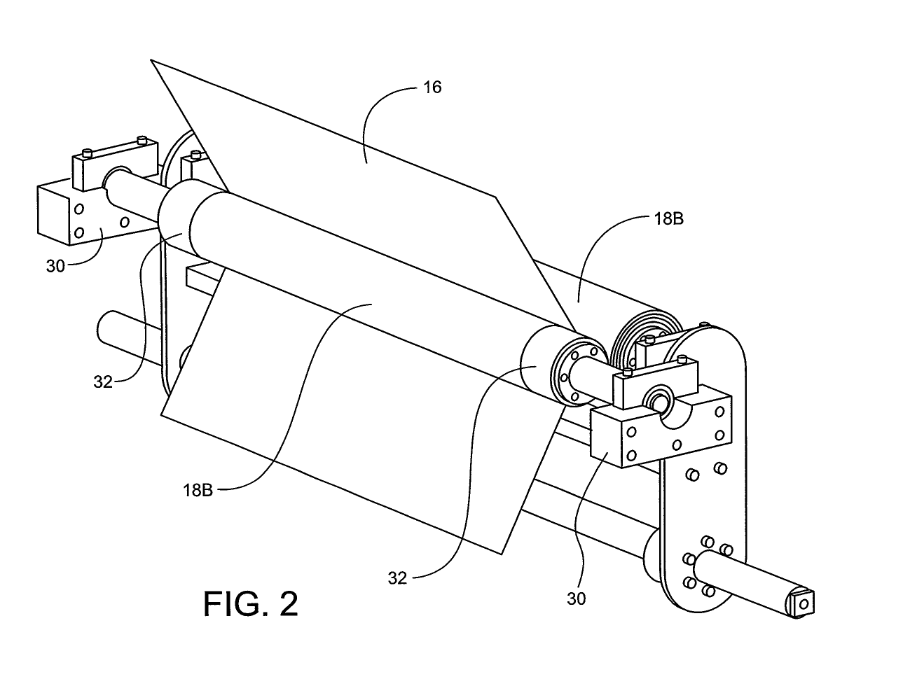

A pair of conductive nip rollers may be used as part of the Hipot tester described herein. FIG. 2 illustrates just one exemplary embodiment, by way of example only, of a pair of conductive nip rollers according to the instant invention. However, various other embodiments may exist. For example, within the instant invention, the conductive nip rollers may be made, in whole or in part, of a conductive polymer. In some embodiments, one roller may be made partially of conductive polymer and also have portions made of non-conductive material, such as non-conductive polymer. Further, within a pair of conductive nip rollers, each roller may have the same diameter, or they may have different diameters. In embodiments where a pair of conductive nip rollers have different diameters, the smaller roller may prove easier to remove from the machine and replace or repair, while the larger roller may wear less compared with the smaller roller. Where a smaller roller is removed for replacement, such replacement may be based on the width of the web material to be tested; thus, various smaller rollers may be included with a system or machine according to the instant invention to ensure the proper size of the smaller roller to correspond to a width of web material to be tested. Further, one roller may be a driven roller, while the other roller may be an idler roller.

In FIG. 2, second ply 16 of the web material to be tested is moving between the pair of conductive rollers 18B. The rollers may be electrically insulated from the machine with non-conductive brackets, such as non-conductive roller mounting brackets 30. The nip rollers (such as the pair of rollers 18B) may actually be used as electrodes with one roller connecting to the high voltage lead of the Hipot tester, and the other opposing roller connecting to the return lead of the tester. Non-conductive web material (such as second ply 16 of the web material 12 to be tested) may run in between. If the material has no flaws, the web should be able to withstand the applied voltage in between the nip rollers. If there is a pinhole or weak spot in the web, a short circuit or arc electrical discharge will occur between the electrode rollers, leaving a burnt mark on the web. The Hipot tester may detect a flaw in the web material by a sudden current surge or arc going through the web material.

The design and construction of the conductive rollers help to enable the machine to test fragile and sensitive web materials. Such conductive rollers may be constructed with metal tubing as the inner portion of the roller and a conductive polymer coating on the outer surface of such metal tubing. Such conductive polymer coating may include, for example, a conductive rubber coating. In various embodiments, for example, the conductive polymer may be conductive because of the inclusion and/or embedding of carbon in the polymer coating. The conductive polymer coating may be used to minimize damage to the web material being tested due to pitting of the surface after Hipot discharges. The opposing nipped rollers may also be different in diameter to randomize the contact points between the two surfaces. As a result, the design may extend the roller covering useful life before becoming too worn at which time it is removed from service and recovered with new polymer. To ensure even and equal surface contact for testing, the two test rollers may be nipped together utilizing a linkage system of one roller moving and applying force against the opposing roller that is in a fixed position. The pressure applied (for example, pneumatic pressure) may depend on the material and its thickness. In various embodiments, such applied pressure may be, by way of example only, 10-80 psi, and in some other embodiments, 20-70 psi, and in still other embodiments, 30-70 psi. Other design details of select embodiments may include some of the following: One nipped roller may have a larger diameter, and such roller may be a non-movable larger diameter nipped roller, which may have its entire face covered with conductive polymer, such as a conductive polymer coating or cover. The opposing roller may be smaller in diameter and may be removable, and it may have the center portion covered with the conductive polymer (such as a conductive polymer coating or cover) while the remaining two sides (see sides 32 in FIG. 2) may be covered with non-conductive polymer (such as a non-conductive polymer coating or cover). In various embodiments, such non-conductive polymer coating or cover on the sides (such as sides 32) may be a different color from the color of the conductive polymer cover or coating in the center portion of the nip roller. This design may be used to prevent wide web wrinkling at the nip point (which wrinkling may occur in other embodiments of the present invention, when one nip roller is completely covered with conductive polymer coating or cover, does not include sides such as sides 32 covered with non-conductive polymer cover or coating and is shorter than the other nipped roller). Such a multi-colored design may also help an operator visually see the coverage of web over the conductive portion of the roller. The conductive width of the removable roller can be varied to accommodate different web width. In some embodiments, the guideline for choosing the right roller may be that the web should be about ½″ wider on each side than the conductive area of the removable nip roller. Although such a design may leave, by way of example, ½″ of web material on each side that is not Hipot tested, such sides of material often are trimmed off, for example, during slitting before shipping to the customers.

As mentioned above, FIG. 2 provides a detailed drawing of a pair of conductive rubber nip rollers designed for continuous web material testing in accordance with one embodiment of the instant invention.

(ii) Static Removal:

To ensure the accuracy of the voltage applied for the Hipot test, the static charge of the web may be neutralized using anti-static bars (such as anti-static bars 20A and 20B in FIG. 1) before entering Hipot testing nip rollers. After Hipot testing, static charge held by the web material may be removed immediately through grounded rollers (such as grounded rollers 22A and 22B) and then by an anti-static bar (such as anti-static bars 26A and 26B) at the rewind (such as rewind 28A or 28 B). This may ensure that there may be no significant charge left in the web as it is rewound onto the collection cores.

(iii) Flaw Detection and Mapping:

After a defect is detected by the Hipot tester, an output signal may be sent to the optical inspection system to look for the burnt mark. The web distance between the Hipot testing rollers and the camera inspection system is known. With input signals from the PLC detecting the line speed of the web passing through the tester, the optical inspection system can calculate and distinguish the defect burnt mark from other flaws. The optical inspection operation may be fully automated, and its start and stop signals may be synchronized with the testing machine and Hipot testers. At the end of each test, a burnt mark flaw map and count summary may be generated automatically (see FIG. 3 as an example). The flaw count may be a quality indicator of the tested material; and the map will help to identify the location of the defects and whether there may be any specific pattern of defects in the tested material, like a repeating pattern of defects, caused by the manufacturing process or equipment. Regarding the map and its output serving as a quality indicator, a customer for a given sheet material may have various specifications requiring that a given roll of sheet material purchased cannot have more than a certain number of defects; using the system, machine, apparatus, and/or methods described herein, the map, flaw count, and output of the system can help a manufacturer determine whether or not a given roll of material has met the customer's specifications. Using the map, the output of the system, and/or the pattern of flaws to determine that a repeating pattern of defects existed for a particular roll may be crucial, in that the manufacturing process or the equipment could be cleaned and/or improved to eliminate such pattern of defects (by way of example only, output from the map may steer a user to realign part of the equipment, clean part of the equipment, or the like).

In the example map shown in FIG. 3, a roll of test material, having a roll length of 14.237 meters and a width of 771.85 mm, was tested. For this embodiment, the roll of test material included polymeric microporous membrane, an insulating material. More particularly, the roll of test material was a trilayer roll of microporous membrane having a total membrane thickness of about 16 μm and including PP/PE/PP as the three layers of the trilayer structure. The roll of material was unwound according to the process described above and was subjected to Hipot testing using a system and various methods according to embodiments of the present invention, here, at a line speed of 12.2 feet per minute. The map in FIG. 3 shows a map of seven total defects and the downweb and crossweb position of each defect. Six of the seven defects shown on the map of FIG. 3 occurred in a straight line at approximately the same crossweb position. This means that the example map of FIG. 3 shows a repeating pattern of defects in the tested roll in that these six defects are all on one side of the web or sheet material. Such a repeating pattern may signify to the user or the manufacturer that some problem exists with that part of the equipment or process, and improvements may be made based on the output of this map. One out of the seven defects shown on the map of FIG. 3 is located at a different crossweb position than the six other defects. That defect can be interpreted as a place of random failure of the material and does not signify a repeating pattern of defects. Such a random failure, if not matched on the same map with a repeating pattern of defects, likely would be within a customer's specifications for a given roll of web material; thus, such a roll of material containing only such random defects within a certain range would not have to be destroyed or modified in some way.

(iv) Hipot Tester and Set Up Parameters:

In various embodiments of the instant invention, an AC/DC Hipot tester with insulation resistance, continuity, and USB/RS232 interface may be used. In one embodiment, as shown herein, the machine may be a 7650 HypotULTRA III Hipot tester, commercially available from Associated Research, Inc. While setting up the system and machine, a user may select various settings for the Hipot tester. In one particular embodiment, where a polymeric microporous membrane material is tested, and where such membrane material is suitable for use as part or all of a battery separator, the setup parameters for the Hipot tester may be in accordance with Table 1, below:

TABLE 1

| Test type | DCW | |
|---|---|---|
| Voltage | 1500 | V |
| Max Lmt | 200 | μA |
| Min Lmt | 0.0 | μA |
| Ramp UP | 0.1 | s |
| Dwell | 999.9 | s |
| Ramp ON | 0.0 | s |
| Connect | off | |
| Ramp HI | off | |
| Charge LO | 0.0 | μA |
| Arc Detect | ON | |
| Arc Sense | 9 | |
| Continuity | Off | |
| Scanner | 00000000 | |
| Prompt | | |

Regarding Table 1 above, the Hipot test type is a direct current withstand test. The voltage used for Hipot testing may be material dependent. Thickness, porosity and application requirement may also be taken into consideration for the voltage selection. By way of example, for testing battery separators of 16-40 μm thickness that are made of polypropylene (PP) and/or polyethylene (PE), a DC voltage of 600-1600V may be used. In various embodiments, such voltage may be 1000-1500V. For thinner test material (for example, material that is less than or equal to about 9-10 microns in thickness), lower withstand voltages may be used, by way of example only, 1000V. In the embodiment described in Table 1, a voltage of 1500V is used. Table 1 contains the setup parameters used to detect pinholes, repeating patterns, surface damage and other imperfection in an insulating material to be tested (such as microporous membranes for use in or for use as battery separators). In Table 1 above, the max current limit is 200 μA, it means, if the tester detects leak current greater than 200 μA going through a spot, it will count it as a flaw. Regarding the ramp up of 0.1 seconds, if a voltage is immediately discharged in a hole or defect in the material, a short occurs, and then the machine ramps back up the desired voltage (here, 1500V) in 0.1 seconds. Other settings in Table 1 are explainable by Hipot tester manual. A typical line speed for running Hipot testing to inspect thin, microporous polymer material, such as, battery separator may be, for example, 5-25FT/min. Under this speed, pinholes may be detected around 650-750V, and other non-hole defects can be detected at higher voltage.

In accordance with at least selected embodiments, the instant invention relates to a new, improved or optimized continuous web inline testing apparatus, defect mapping system, and/or related methods, a continuous web inline testing apparatus adapted for use in a defect mapping system and to related methods of testing and mapping. The instant invention also relates to a new, improved or optimized continuous inline Hipot testing system, an inline Hipot testing system on continuous non-conductive web material that may detect defects and then map and record such defects automatically by a line scan camera system for quality grading purposes, and/or the like.

In accordance with at least certain selected embodiments, an industrial size continuous Hipot testing system with defect mapping capability capable of finding pinholes, weak spots, and/or embedded conductive particles in non-conductive sheet materials. Continuous testing is made possible through a pair of uniquely designed rollers, such as conductive polymer rollers. Automatic defect mapping is also incorporated into the system through the integration of the Hipot testing and line scan camera systems. The unit potentially has wide applications in many industries, including, by way of example, semi-conductor and electronics, medical, high end packaging, and so forth.

In accordance with certain embodiments, aspects, or objects, the instant invention may relate to new, improved or optimized continuous inline Hipot testing systems, to inline Hipot testing on continuous non-conductive web materials, which testing may detect defects and then map and record such defects automatically by a line scan camera system for quality grading purposes, to an industrial size continuous Hipot testing system with defect mapping capability capable of finding pinholes, weak spots and embedded conductive particles in non-conductive sheet materials, to continuous testing through a pair of uniquely designed conductive polymer rollers, to automatic defect mapping incorporated into the system through the integration of the Hipot testing and line scan camera systems, to potential wide applications in many industries, by way of example, semi-conductor and electronics, medical, high end packaging, and/or the like.

In at least selected embodiments, an industrial size continuous Hipot testing system has defect mapping capability capable of finding pinholes, weak spots, and/or embedded conductive particles in non-conductive sheet materials. Continuous testing is made possible through a pair of uniquely designed rollers, such as conductive polymer rollers. Automatic defect mapping is also incorporated into the system through the integration of the Hipot testing and line scan camera systems. The unit potentially has wide applications in many industries, such as, for example, semi-conductors and electronics, medical, high end packaging, and so forth.

The present invention may be embodied in other forms without departing from the spirit and the essential attributes thereof, and, accordingly, reference should be made to the appended claims, rather than to the foregoing specification, as indicating the scope of the invention. Additionally, the invention illustratively disclosed herein suitably may be practiced in the absence of any element which is not specifically disclosed herein.

1. A continuous web inline Hipot testing and web defect mapping system.

2. The continuous web inline Hipot testing and web defect mapping system of claim 1, wherein said web includes a non-conductive web material.

3. The continuous web inline Hipot testing and web defect mapping system of claim 1, wherein said system maps one or more defects in said web and wherein said web includes a non-conductive web material.

4. The continuous web inline Hipot testing and web defect mapping system of claim 1, wherein said web defects are selected from the group consisting of holes, weak spots, pinholes, defects embedded with one or more conductive particles, and combinations thereof, and wherein said web is selected from the group consisting of insulating sheet material for use in electronics or batteries, microporous membrane for use in rechargeable lithium ion batteries, separators for use in lead acid batteries, and combinations thereof.

5. The continuous web inline Hipot testing and web defect mapping system of claim 1, wherein said web includes one or more non-conductive sheet materials for use in a medical application or a packaging application and wherein said Hipot testing comprises testing for one or more leaks in said non-conductive sheet material.

6. The continuous web inline Hipot testing and web defect mapping system of claim 1 comprising:
a pair of conductive nip rollers;
a static removal device;
a line scan camera system; and
a Hipot testers.

7. The continuous web inline Hipot testing and web defect mapping system of claim 6, wherein said pair of conductive nip rollers comprise rolling electrodes to conduct said Hipot testing continuously.

8. The continuous web inline Hipot testing and web defect mapping system of claim 6, wherein said pair of conductive nip rollers comprise a conductive polymer, a conductive rubber, or a combination thereof.

9. The continuous web inline Hipot testing and web defect mapping system of claim 6, wherein the system is adapted to test webs of different web width by changing out one of said nip rollers.

10. The continuous web inline Hipot testing and web defect mapping system of claim 6, wherein said nip rollers are electrically insulated from other portions of the system with non-conductive brackets.

11. The continuous web inline Hipot testing and web defect mapping system of claim 6, wherein said nip rollers are used as electrodes with one roller connecting to a high voltage lead of said Hipot tester, and the other opposing roller connecting to a return lead of said Hipot tester.

12. The continuous web inline Hipot testing and web defect mapping system of claim 6, wherein the web comprises non-conductive web material running in between said nip rollers.

13. The continuous web inline Hipot testing and web defect mapping system of claim 6, wherein said Hipot tester may detect said web defects by a sudden current surge or arc going through the web, whereby if the web has no web defects, the web will withstand an applied voltage in between the nip rollers, and whereby if there is a web defect, a short circuit or arc electrical discharge will occur between the nip rollers, leaving a burnt mark on the web.

14. The continuous web inline Hipot testing and web defect mapping system of claim 6, wherein the nip rollers are constructed with metal tubing as an inner portion and conductive polymer coating as an outer portion, wherein the conductive polymer coating is used to minimize damage to the web being tested due to pitting of the surface of the roller after Hipot discharges.

15. The continuous web inline Hipot testing and web defect mapping system of claim 6, wherein the nipped rollers are different in diameter to randomize contact points between surfaces of said rollers.

16. The continuous web inline Hipot testing and web defect mapping system of claim 6, wherein the two nip rollers are nipped together utilizing a linkage system of one roller moving and applying force against an opposing roller that is in a fixed position.

17. The continuous web inline Hipot testing and web defect mapping system of claim 6, wherein the non-movable larger diameter of said nipped roller having its entire face covered with conductive polymer, and said opposing roller being smaller, removable, and having the center portion covered with the conductive polymer while the remaining two sides being covered with non-conductive polymer of a different color, thereby preventing wide web wrinkling at the nip point, and helping the operator visually see the coverage of web over the conductive portion of the roller, wherein the web being about ½″ wider on each side than the conductive area of the removable nip roller, wherein said nip rollers being as shown in FIG. 2, wherein said static removal devices including anti-static bars positioned before entering said Hipot testing nip rollers thereby neutralizing the static charge of the web and ensuring the accuracy of the voltage applied for the Hipot test, wherein said static removal devices including grounded rollers immediately after Hipot testing for immediately removing static charge held by the web material, wherein said static removal devices including an anti-static bar at the rewind adapted for ensuring that there may be no significant charge left in the web as it is rewound onto the collection cores, wherein said line scan camera system being adapted for flaw detection and mapping, wherein, after a defect is detected by the Hipot tester, said line scan camera system being adapted for sending an output signal to an optical inspection system to look for the burnt mark, wherein with input signals from said PLC detecting the line speed of the web passing through the tester, the optical inspection system can calculate and distinguish the defect burnt mark from other flaws, wherein the optical inspection operation being fully automated, and its start and stop signals being synchronized with the testing machine and Hipot testers, wherein at the end of each test, a burnt mark flaw map and count summary being generated automatically (FIG. 3 as an example), wherein the flaw count may be a quality indicator of the tested material; and the map being adapted to help identify whether there may be any specific pattern, like a repeating pattern, caused by manufacturing process or equipment, wherein said Hipot testers having insulation resistance, continuity, and USB/RS232 interface, wherein the Hipot testers being 7650 HypotULTRA III Hipot testers made by Associated Research Inc., and/or wherein the Hipot testing setup for battery separators my include

| Test type | DCW | |
|---|---|---|
| Voltage | 1500 | V |
| Max Lmt | 200 | μA |
| Min Lmt | 0.0 | μA |
| Ramp UP | 0.1 | s |
| Dwell | 999.9 | s |
| Ramp ON | 0.0 | s |
| Connect | off | |
| Ramp HI | off | |
| Charge LO | 0.0 | μA |
| Arc Detect | ON | |
| Arc Sense | 9 | |
| Continuity | Off | |
| Scanner | 00000000 | |
| Prompt | | |

18. A method of Hipot testing and defect mapping.

19. A method of Hipot testing and defect mapping as shown and described herein.

20. A method of Hipot testing and defect mapping including the step of utilizing the continuous web inline Hipot testing and defect mapping system according to claim 1.

21. The method of Hipot testing and defect mapping according to claim 20 wherein the operating sequences of the system including:
a. a roll of sheet material composed two plies is loaded to the unwind arbor;
b. the plies may first be separated, then Hipot tested for pinholes and weak spots;
c. the burnt spots resulted from the Hipot failures may be mapped by line scan cameras for quality grading purpose;
d. the tested material is then collected at the rewinds as rolls; or
e. combinations thereof.

22. The method of Hipot testing and defect mapping according to claim 21 including a step of prepare for testing including:
a. a roll of material being loaded onto the unwind arbor;
b. tie in footage then being pulled from the roll, separated, and threaded through the machine to the rewinds;
c. to begin the web inspection, the winder may run at “crawl” speed with the Hipot testers not activated;
d. while doing this, the web may be aligned to fully cover the smaller and removable conductive polymer roller making sure the two rollers do not make contact with one another; or
e. combinations thereof.

23. The method of Hipot testing and defect mapping according to claim 22 including the following starting steps:
a. the operator pushing the “Run” button on the HMI and the machine being programmed to run at a designated preset speed for a predetermined length;
b. when the machine is started, the Hipot tester(s) and optical inspection system being activated automatically through the PLC;
c. the unwinding web material first being separated;
d. then the static being discharged by an anti-static bar;
e. the separate webs then being Hipot tested in between the nipped conductive polymer rollers;
f. after the testing, the web going over grounded rollers to remove the charge stored in the material;
g. the web then passing through the optical inspection area of the machine for the mapping of the burnt defects;
h. a detailed roll map and report showing cross and down web positions of the defect then being created automatically at the end of the run; or
i. combinations thereof.
